(19) United States
(12) Patent Application Publication
(10) Pub. No.: US 2022/0399462 A1
(43) Pub. Date: Dec. 15, 2022

(54) THIN FILM TRANSISTOR AND MANUFACTURING METHOD FOR THE SAME

(71) Applicant: ADRC.CO. KR, Seoul (KR)

(72) Inventors: Jin JANG, Seoul (KR); Suhui LEE, Seoul (KR)

(21) Appl. No.: 17/687,854

(22) Filed: Mar. 7, 2022

(30) Foreign Application Priority Data
Jun. 15, 2021 (KR) 10-2021-0077507

(51) Int. Cl. H01L 29/786; H01L 29/66

(52) U.S. Cl. CPC H01L 29/78618; H01L 29/78696; H01L 29/78663; H01L 29/7869; H01L 29/6675

(57) ABSTRACT

A thin film transistor according to an embodiment includes a first semiconductor, a gate electrode overlapping the first semiconductor, a second semiconductor contacting a portion of the first semiconductor, and a source electrode and a drain electrode contacting the second semiconductor, the first semiconductor includes an oxide semiconductor, and the second semiconductor includes silicon.

### CROSS-REFERENCE TO RELATED APPLICATION

This application claims priority to and the benefit of Korean Patent Application No. 10-2021-0077507 filed in the Korean Intellectual Property Office on Jun. 15, 2021, the entire contents of which are incorporated herein by reference.

### BACKGROUND

### 1. Field

The present disclosure relates a transistor and a manufacturing method thereof.

### 2. Description of the Related Art

A thin film transistor is a switching element using three terminals of a gate electrode to which a control signal is applied, a source electrode to which a data voltage is applied, and a drain electrode to output the data voltage. In addition, this thin film transistor includes an active layer overlapping the gate electrode as a channel layer, and the active layer includes a semiconductor.

On the other hand, with the development of a display technology including a thin film transistor, the development of a thin film transistor capable of high-speed driving is urgently needed. For this purpose, a technology using an oxide semiconductor with high electron mobility as an active layer has been developed, but it is required to develop a thin film transistor with improved performance so that it can be used for high-speed operation.

The above information disclosed in this Background section is only for enhancement of understanding of the background of the described technology, and therefore it may contain information that does not form the prior art that is already known in this country to a person of ordinary skill in the art.

### SUMMARY

Embodiments are to provide a thin film transistor including an oxide semiconductor whose performance is improved so as to be used for high-speed driving, and a manufacturing method thereof.

However, the problems to be solved by the embodiments are not limited to the above-described problems, and may be variously expanded in the range of the technical ideas included in the embodiments.

A thin film transistor according to an embodiment includes a first semiconductor, a gate electrode overlapping the first semiconductor, a second semiconductor contacting a portion of the first semiconductor, and a source electrode and a drain electrode contacting the second semiconductor, wherein the first semiconductor includes an oxide semiconductor, and the second semiconductor includes silicon.

The first semiconductor may include a channel region overlapping the gate electrode, a source region and a drain region contacting the second semiconductor, and the second semiconductor may include a first portion contacting the source region of the first semiconductor and a second portion contacting the drain region of the first semiconductor.

Resistances of the source region and the drain region of the first semiconductor may be reduced by the second semiconductor contacting the first semiconductor.

The source region of the first semiconductor and the first portion of the second semiconductor may be in ohmic contact with the source electrode, and the drain region of the first semiconductor and the second portion of the second semiconductor may be in ohmic contact with the drain electrode.

The second semiconductor may include a hydrogenated amorphous silicon.

The second semiconductor may include a first impurity of an N-type or a second impurity of a P-type, and the first semiconductor may include the first impurity or the second impurity of the second semiconductor.

Values of sheet resistances of the source region and the drain region of the first semiconductor may be lower than a value of a sheet resistance of the channel region.

Values of carrier concentrations of the source region and the drain region of the first semiconductor may be greater than a value of a carrier concentration of the channel region.

The thickness of the second semiconductor may be at least 5 nm to 60 nm.

The thin film transistor may further include a protection member disposed on the channel region of the first semiconductor layer, and the first portion and the second portion of the second semiconductor layer may overlap a portion of the protection member and be spaced apart from each other on the protection member.

The source electrode may be disposed over the first portion of the second semiconductor, the drain electrode may be disposed over the second portion of the second semiconductor, the first portion of the second semiconductor and the source electrode may be patterned together to have the same planar shape, and the second portion of the second semiconductor and the drain electrode may be patterned together to have the same planar shape.

A method of manufacturing a thin film transistor according to an embodiment includes: forming a first semiconductor layer including an oxide semiconductor on a substrate; forming a gate electrode overlapping the first semiconductor layer; depositing a second semiconductor layer including silicon on the first semiconductor layer and the gate electrode to contact a portion of the first semiconductor layer; and forming a source electrode and a drain electrode contacting the second semiconductor layer.

The first semiconductor layer may be formed to include a channel region overlapping the gate electrode, and a source region and a drain region contacting the second semiconductor layer. The second semiconductor layer may be formed to include a first portion contacting the source region of the first semiconductor and a second portion contacting the drain region of the first semiconductor.

The thin film transistor manufacturing method may further include patterning the second semiconductor layer to form the first portion contacting the source region of the first semiconductor and the second portion contacting the drain region of the first semiconductor.

According to embodiments, it is possible to provide a thin film transistor with improved performance to be used for high-speed driving, and a method for manufacturing the same.

However, the effects of the embodiments are not limited to the above-described effects, and it is apparent that various extensions may be made without departing from the spirit and scope of the present invention.

### BRIEF DESCRIPTION OF THE DRAWINGS

FIG. 1 is a cross-sectional view of a thin film transistor according to an embodiment.

FIG. 2 to FIG. 8 are cross-sectional views showing a thin film transistor manufacturing process according to an embodiment.

FIG. 9 is a cross-sectional view of a thin film transistor according to another embodiment.

FIG. 10 to FIG. 12 are photographs showing the results of one experimental example.

FIG. 13 to FIG. 15 are graphs showing results of another experimental example.

FIG. 16 to FIG. 18 are graphs showing results of another experimental example.

FIG. 19 to FIG. 21 are graphs showing results of another experimental example.

FIG. 22 and FIG. 23 are graphs showing results of another experimental example.

FIG. 24 to FIG. 26 are graphs showing results of another experimental example.

FIG. 27 to FIG. 30 are graphs showing results of another experimental example.

### DETAILED DESCRIPTION

The present disclosure will be described more fully hereinafter with reference to the accompanying drawings, in which embodiments are shown. As those skilled in the art would realize, the described embodiments may be modified in various different ways, all without departing from the spirit or scope of the present disclosure.

To clearly describe the present disclosure, parts that are irrelevant to the description are omitted, and like numerals refer to like or similar constituent elements throughout the specification.

The accompanying drawings are provided only in order to allow embodiments disclosed in the present specification to be easily understood and are not to be interpreted as limiting the spirit disclosed in the present specification, and it is to be understood that the present disclosure includes all modifications, equivalents, and substitutions without departing from the scope and spirit of the present disclosure.

Further, since sizes and thicknesses of constituent members shown in the accompanying drawings are arbitrarily given for better understanding and ease of description, the present disclosure is not limited to the illustrated sizes and thicknesses. In the drawings, the thicknesses of layers, films, panels, regions, etc., are exaggerated for clarity. In the drawings, the thickness of layers, films, panels, regions, etc., are exaggerated for clarity. In the drawings, for better understanding and ease of description, the thicknesses of some layers and areas are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, in the specification, the phrase “in a plan view” means when an object portion is viewed from above, and the phrase “in a cross-sectional view” means when a cross-section taken by vertically cutting an object portion is viewed from the side.

In addition, in the specification, “connected” means that two or more components are not only directly connected, but two or more components may be connected indirectly through other components, physically connected as well as being electrically connected, or it may have been referred to as different names depending on the location or function, but may mean integral.

Hereinafter, various embodiments and variations will be described in detail with reference to drawings.

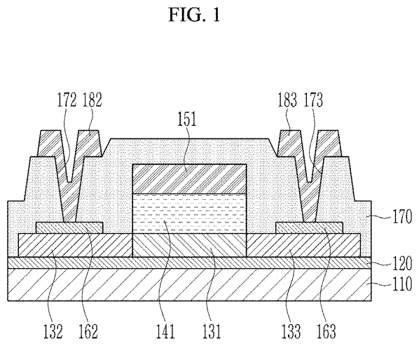

First, a thin film transistor according to an embodiment will be described with reference to FIG. 1. FIG. 1 is a cross-sectional view of a thin film transistor according to an embodiment.

Referring to FIG. 1, the buffer layer 120 is disposed on the substrate 110. The buffer layer 120 may have a single-layer structure or a multi-layer structure. Although the buffer layer 120 is illustrated as a single layer in FIG. 1, it may be a multi-layer according to an embodiment. The buffer layer 120 may include an organic insulating material or an inorganic insulating material. For example, the buffer layer 120 may include at least one of a silicon nitride (SiNx), a silicon oxide (SiOx), and a silicon oxynitride (SiOxNy).

The first semiconductor layer 131, 132, and 133 including a first region 131, a second region 132, and a third region 133 is disposed on the buffer layer 120.

The first semiconductor layer 131, 132, and 133 may include an oxide semiconductor. Oxide semiconductors are monolithic metal oxides such as indium (In) oxide, tin (Sn) oxide, or zinc (Zn) oxide, In—Zn-based oxides, Sn—Zn-based oxides, Al—Zn-based oxides, Zn—Mg-based oxides, binary metal oxides such as Sn—Mg-based oxides, In—Mg-based oxides, or In—Ga-based oxides, In—Ga—Zn-based oxides, In—Al—Zn-based oxides, In—Sn—Zn-based oxides, Sn—Ga—Zn-based oxides, Al—Ga—Zn-based oxides, Sn—Al—Zn-based oxides, In—Hf—Zn-based oxides, In—La—Zn-based oxides, In—Ce—Zn-based oxides, In—Pr—Zn-based oxides, In—Nd—Zn-based oxides, In—Sm—Zn-based oxides, In—Eu—Zn-based oxides, In—Gd—Zn-based oxides, In—Tb—Zn-based oxides, In—Dy-ternary metal oxides such as Zn-based oxides, In—Ho—Zn-based oxides, In—Er—Zn-based oxides, In—Tm—Zn-based oxides, In—Yb—Zn-based oxides, or In—Lu—Zn-based oxides; and In—Sn—Ga—Zn-based oxides, In—Hf—Ga—Zn-based oxides, In—Al—Ga—Zn-based oxides, In—Sn—Al—Zn-based oxides, and In—Sn—Hf—Zn—based oxides, and alternatively, it may include at least one of a quaternary metal oxide such as an In—Hf—Al—Zn-based oxide. For example, the first semiconductor layer 131, 132, and 133 may include Indium-Gallium-Zinc Oxide (IGZO) among the In—Ga—Zn-based oxides.

The first region 131 of the first semiconductor layer 131, 132, and 133 is a channel region, and the second region 132 and the third region 133 of the first semiconductor layer 131, 132, and 133 are a source region and a drain region.

The sheet resistance of the first region 131 that is the channel region of the first semiconductor layer 131, 132, and 133 is greater than the sheet resistances of the second region 132 that is the source region of the first semiconductor layer 131, 132, and 133 and the third region 133 that is the drain region of the first semiconductor layer 131, 132, and 133. The carrier concentration of the first region 131 is higher than the carrier concentrations of the second region 132 and the third region 133.

The second region 132 and the third region 133 of the first semiconductor layer 131, 132, and 133 may include an impurity, for example, an N-type impurity or a P-type impurity. For example, the N-type impurity may be P (phosphorus), As (arsenic), or Sb (antimony), and the P-type impurity may be B (boron), Al (13), or In (indium).

Impurities may not be included in the first region 131, which is a channel region of the first semiconductor layer 131, 132, and 133. Concentrations of the impurities in the second region 132 and the third region 133 of the first semiconductor layer 131, 132, and 133 are may be higher than the concentration of the impurities in the first region 131 of the first semiconductor layer 131, 132, and 133.

A gate insulating layer 141 is disposed on the first region 131 of the first semiconductor layer 131, 132, and 133. The gate insulating layer 141 may include an organic insulating material or an inorganic insulating material. For example, the gate insulating layer 141 may include a silicon nitride, a silicon oxide, a silicon oxynitride, or tetraethyl orthosilicate (TEOS).

A gate electrode 151 is disposed on the gate insulating layer 141. The gate electrode 151 is disposed to overlap the first region 131 of the first semiconductor layer 131, 132, and 133, and the gate insulating layer 141 is disposed between the first region 131 of the first semiconductor layer 131, 132, and 133 and the gate electrode 151.

The gate electrode 151 may be a multilayer in which a metal film including any one of copper (Cu), a copper alloy, aluminum (Al), an aluminum alloy, molybdenum (Mo), and a molybdenum alloy is stacked.

The second semiconductor layers 162 and 163 are disposed on the second region 132 and the third region 133 of the first semiconductor layer 131, 132, and 133.

The second semiconductor layers 162 and 163 include a first portion 162 contacting the second region 132 of the first semiconductor layer 131, 132, and 133 and a second portion 163 contacting the third region 133 of the first semiconductor layer 131, 132, and 133.

The second semiconductor layers 162 and 163 include an amorphous silicon, and more specifically, the second semiconductor layers 162 and 163 include a hydrogenated amorphous silicon (a-Si:H).

The second semiconductor layers 162 and 163 may include impurities, for example, N-type impurities or P-type impurities.

The impurities included in the second semiconductor layers 162 and 163 may be the same as impurities included in the second region 132 and the third region 133 of the first semiconductor layer 131, 132, and 133.

The first portion 162 of the second semiconductor layers 162 and 163 is in ohmic contact with the second region 132 of the first semiconductor layer 131, 132, and 133, and the second portion 163 of the second semiconductor layers 162 163 is in ohmic contact with the third region 133 of the first semiconductor layer 131, 132, and 133.

The thickness of the second semiconductor layers 162 and 163 may be about 20 nm or more, and more specifically, the thickness of the second semiconductor layers 162 and 163 may be about 20 nm to about 100 nm. When the thickness of the second semiconductor layers 162 and 163 is about 20 nm or more, the sheet resistances of the second regions 132 and the third regions of the first semiconductor layer 131, 132, and 133 contacting the second semiconductor layers 162 and 163 are of the region 133 may decrease and the carrier concentrations of the second regions 132 and the third regions 133 of the first semiconductor layer 131, 132, and 133 contacting the second semiconductor layers 162 and 163 may increase.

A passivation layer 170 is disposed on the first semiconductor layer 131, 132, and 133, the second semiconductor layers 162 and 163, the gate insulating layer 141, and the gate electrode 151. The passivation layer 170 may include at least one of a silicon nitride, a silicon oxide, a silicon oxynitride, and tetraethyl orthosilicate (TEOS), and it may be made of an organic material such as a polyacrylate resin or a polyimide resin or may be a laminated film of the organic material and an inorganic material.

The passivation layer 170 has a first contact hole 172 overlapping the first portion 162 and a second contact hole 173 overlapping the second portion 163.

A source electrode 182 and a drain electrode 183 are disposed on the passivation layer 170. The source electrode 182 is connected to the second region 132 that is the source region of the first semiconductor layer 131, 132, and 133 through the first portion 162 of the second semiconductor layers 162 and 163 exposed by the first contact hole 172 of the passivation layer 170, and the drain electrode 183 is connected to the third region 133 that is the drain region of the first semiconductor layer 131, 132, and 133 through the second portion 163 of the second semiconductor layers 162 and 163 exposed by the second contact hole 173 of the passivation layer 170.

The source electrode 182 and the drain electrode 183 may include an aluminum-based metal, a silver-based metal, or a copper-based metal having low resistivity, and for example, may be three-layered of a lower film containing a refractory metal such as titanium, molybdenum, chromium, tantalum, or an alloy thereof, an intermediate film containing a low resistivity aluminum-based metal, a silver-based metal, or a copper-based metal, and an upper film containing a refractory metal such as titanium, molybdenum, chromium, and tantalum.

The gate electrode 151, the source electrode 182, and the drain electrode 183 may form a thin film transistor (TFT) together with the first semiconductor layer 131, 132, and 133 and the second semiconductor layers 162 and 163, and the channel of the thin film transistor is formed in the first region 131 between the second region 132 serving as the source region and the third region 133 serving as the drain region of the semiconductors 131, 132, and 133.

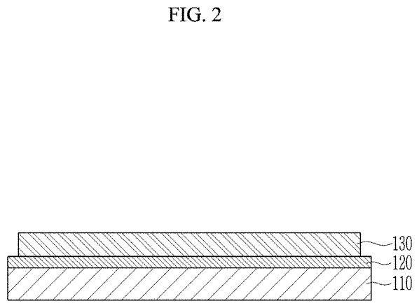

Now, a method of manufacturing a thin film transistor according to an embodiment will be described with reference to FIGS. 2 to 8 together with FIG. 1. FIG. 2 to FIG. 8 are cross-sectional views illustrating a thin film transistor manufacturing process according to an embodiment.

Referring to FIG. 2, the buffer layer 120 is deposited on the substrate 110, and the first semiconductor layer 130 is deposited on the buffer layer 120.

The buffer layer 120 may include an organic insulating material or an inorganic insulating material. For example, the buffer layer 120 may include at least one of a silicon nitride (SiNx), a silicon oxide (SiOx), and a silicon oxynitride (SiOxNy). addition, the first semiconductor layer 130 may include an oxide semiconductor. Oxide semiconductors are monolithic metal oxides such as indium oxide (In), tin oxide (Sn), or zinc oxide (Zn), In—Zn-based oxides, Sn—Zn-based oxides, Al—Zn-based oxides, Zn—Mg-based oxides, binary metal oxides such as Sn—Mg-based oxides, In—Mg-based oxides, or In—Ga-based oxides, In—Ga—Zn-based oxides, In—Al—Zn-based oxides, In—Sn—Zn-based oxides, Sn—Ga—Zn-based oxides, Al—Ga—Zn-based oxides, Sn—Al—Zn-based oxides, In—Hf—Zn-based oxides, In—La—Zn-based oxides, In—Ce—Zn-based oxides, In—Pr—Zn-based oxides, In—Nd—Zn-based oxides, In—Sm—Zn-based oxides, In—Eu—Zn-based oxides, In—Gd—Zn-based oxides, In—Tb—Zn-based oxides, In—Dy-ternary metal oxides such as Zn-based oxides, In—Ho—Zn-based oxides, In—Er—Zn-based oxides, In—Tm—Zn-based oxides, In—Yb—Zn-based oxides, or In—Lu—Zn-based oxides; and In—Sn—Ga—Zn-based oxides, In—Hf—Ga—Zn-based oxides, In—Al—Ga—Zn-based oxides, In—Sn—Al—Zn-based oxides, In—Sn—Hf—Zn-based oxides, and alternatively, it may include at least one of a quaternary metal oxide such as an In—Hf—Al—Zn-based oxide. For example, the first semiconductor layer 131, 132, and 133 may include Indium-Gallium-Zinc Oxide (IGZO) among the In—Ga—Zn-based oxides.

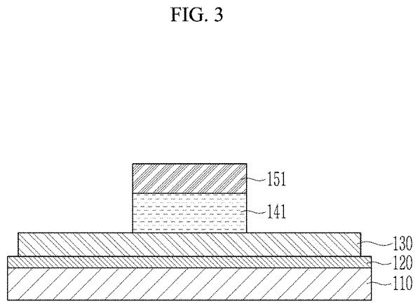

As shown in FIG. 3, a gate insulating layer 141 and a gate electrode 151 are formed on the first semiconductor layer 130. At this time, after sequentially depositing an insulating layer forming a gate insulating film and a metal layer forming a gate electrode on the first semiconductor layer 130, the metal layer and the insulating layer are sequentially etched to form the gate insulating film 141 and the gate electrode 151. The gate insulating layer 141 may include an organic insulating material or an inorganic insulating material. For example, the gate insulating layer 141 may include a silicon nitride, a silicon oxide, a silicon oxynitride, or tetraethyl orthosilicate (TEOS), and the gate electrode 151 may be a multi-layered metal film including any one of copper (Cu), a copper alloy, aluminum (Al), an aluminum alloy, molybdenum (Mo), and a molybdenum alloy.

The gate insulating layer 141 and the gate electrode 151 are disposed to overlap the first region 131 of the first semiconductor layer 131, 132, and 133 of FIG. 1.

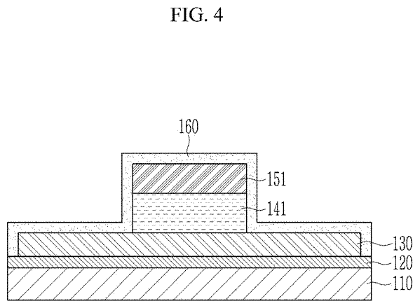

Next, as shown in FIG. 4, a second semiconductor layer 160 is deposited on the first semiconductor layer 130, the gate insulating layer 141, and the gate electrode 151. The second semiconductor layer 160 includes an amorphous silicon, and more specifically, the second semiconductor layer 160 includes a hydrogenated amorphous silicon (a-Si:H).

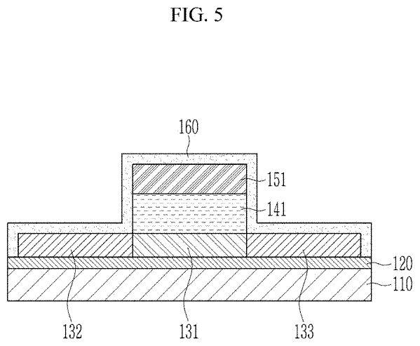

As shown in FIG. 5, by depositing the second semiconductor layer 160 including the hydrogenated amorphous silicon on the first semiconductor layer 130, the gate insulating layer 141, and the gate electrode 151, the second region 132 and the third region 133 of the first semiconductor layer 130 contact the second semiconductor layer 160 without overlapping the gate insulating layer 141 and the gate electrode 151 is metallized by hydrogen contained in the second semiconductor layer 160 to form a source region and a drain region, and at the same time, a first region 131 serving as a channel region is formed between the second region 132 and the third regions 133 of the first semiconductor layer 130.

Accordingly, the sheet resistance of the first region 131 that is the channel region of the first semiconductor layer 131, 132, and 133 is greater than the sheet resistances of the second region 132 and the third region 133 which are the source region and the drain region of the first semiconductor layer 131, 132, and 133, and a carrier concentration of the first region 131 that is a channel region of the first semiconductor layer 131, 132, and 133 is lower than carrier concentrations of the second and third regions 132 and 133 that are the source region and the drain region of the semiconductor layer 131, 132, and 133.

In addition, the second semiconductor layer 160 may include impurities, for example, N-type impurities or P-type impurities. The impurities contained in the second semiconductor layer 160 are diffused into the second region 132 and the third region 133 of the first semiconductor layer 131, 132, and 133 contacting the second semiconductor layer 160 and therefore the impurities contained in the second region 132 and the third region 133 of the first semiconductor layer 131, 132, and 133 may be the same as impurities contained in the second semiconductor layer 160.

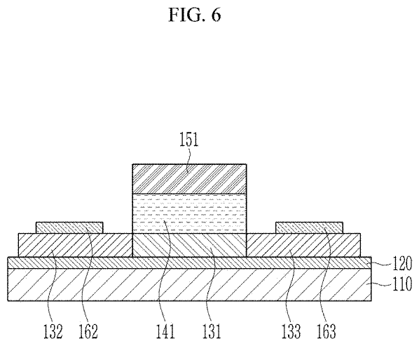

Next, as shown in FIG. 6, the second semiconductor layer 160 is patterned to form a first portion 162 contacting the second region 132 of the first semiconductor layer 131, 132, and 133 and the second portion 163 contacting the third region 133 of the first semiconductor layer 131, 132, and 133.

The first portion 162 of the second semiconductor layers 162 and 163 is in ohmic contact with the second region 132 of the first semiconductor layer 131, 132, and 133, and the second portion 163 of the second semiconductor layer 162 and 163 is in ohmic contact with the third region 133 of the first semiconductor layer 131, 132, and 133.

The thickness of the second semiconductor layers 162 and 163 may be at least about 5 nm to about 60 nm, and the thickness of the second semiconductor layers 162 and 163 may be about 20 nm to about 60 nm. More specifically, when the thickness of the second semiconductor layers 162 and 163 is about 20 nm or more, the sheet resistances of the second region 132 and the third region 133 of the first semiconductor layer 131, 132, and 133 contacting the second semiconductor layers 162 and 163 may decrease and the carrier concentrations of the second region 132 and the third region 133 may increase.

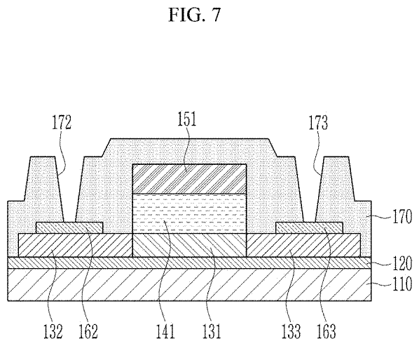

Next, as shown in FIG. 7, a passivation layer 170 is deposited on the first semiconductor layer 131, 132, and 133, the second semiconductor layers 162 and 163, the gate insulating film 141, and the gate electrode 151. The first contact hole 172 overlapping the first portion 162 of the second semiconductor layers 162 and 163 and the second contact hole 173 overlapping the second portion 163 of the second semiconductor layers 162 and 163 are formed in the passivation layer 170.

The passivation layer 170 may include at least one of a silicon nitride, a silicon oxide, a silicon oxynitride, and tetraethyl orthosilicate (TEOS), and it may be made of an organic material such a polyacrylate resin or a polyimide resin or may be a laminated film of the organic material and the inorganic material.

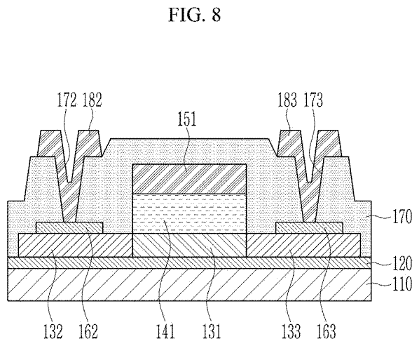

Next, as shown in FIG. 8, a source electrode 182 and a drain electrode 183 are formed on the passivation layer 170. The source electrode 182 is connected to the second region 132 of the first semiconductor layer 131, 132, and 133 through the first portion 162 exposed by the first contact hole 172 of the passivation layer 170 and the drain electrode 183 is connected to the third region 133 of the first semiconductor layer 131, 132, and 133 through the second portion 163 exposed by the second contact hole 173 of the passivation layer 170.

The source electrode 182 and the drain electrode 183 may include an aluminum-based metal, a silver-based metal, or a copper-based metal having low resistivity, and for example, may be three-layered of a lower film containing a refractory metal such as titanium, molybdenum, chromium, tantalum, or an alloy thereof, an intermediate film containing a low resistivity aluminum-based metal, a silver-based metal, or a copper-based metal, and an upper film containing a refractory metal such as titanium, molybdenum, chromium, and tantalum.

As such, according to the manufacturing method of the thin film transistor according to the embodiment, by laminating a second semiconductor layer including hydrogenated amorphous silicon (a-Si:H) on a first semiconductor layer including an oxide semiconductor, the second region 132 and the third region 133 of the first semiconductor layer contacting the second semiconductor layer are metallized by hydrogen included in the second semiconductor layer to form a source region and a drain region, and at the same time, a first region 131 that is a channel region may be formed between the second region 132 of the first semiconductor layer and the third region 133 of the first semiconductor layer. Accordingly, the performance of the transistor can be improved by forming the channel region, the source region, and the drain region in the semiconductor layer including the oxide semiconductor, and contact characteristics between the source region and the drain region and the source electrode and the drain electrode may be improved without complicating the manufacturing process or increasing the manufacturing cost.

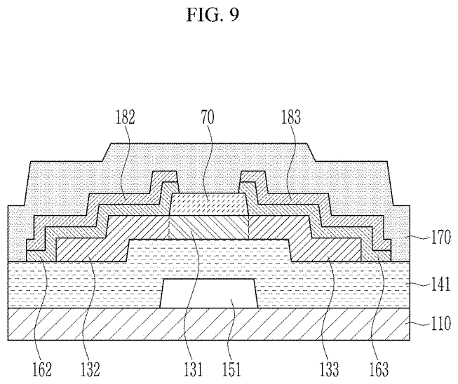

Next, a thin film transistor according to another embodiment will be described with reference to FIG. 9. FIG. 9 is a cross-sectional view of a thin film transistor according to another embodiment.

Referring to FIG. 9, the thin film transistor according to the present embodiment is similar to the thin film transistor according to the embodiment shown in FIG. 1. A detailed description of the same components will be omitted.

Referring to FIG. 9, the gate electrode 151 is disposed on the substrate 110. The gate electrode 151 may be a multilayer including a metal film including any one of copper (Cu), a copper alloy, aluminum (Al), an aluminum alloy, molybdenum (Mo), and a molybdenum alloy.

A gate insulating layer 141 is disposed on the gate electrode 151. The gate insulating layer 141 may include an organic insulating material or an inorganic insulating material. For example, the gate insulating layer 141 may include at least one of a silicon nitride, a silicon oxide, a silicon oxynitride, or tetraethyl orthosilicate (TEOS).

The first semiconductor layer 131, 132, and 133 including the first region 131, the second region 132, and the third region 133 is disposed on the gate insulating layer 141.

The first semiconductor layer 131, 132, and 133 may include an oxide semiconductor. Oxide semiconductors are monolithic metal oxides such as indium oxide (In), tin oxide (Sn), or zinc oxide (Zn), In—Zn-based oxides, Sn—Zn-based oxides, Al—Zn-based oxides, Zn—Mg-based oxides, binary metal oxides such as Sn—Mg-based oxides, In—Mg-based oxides, or In—Ga-based oxides, In—Ga—Zn-based oxides, In—Al—Zn-based oxides, In—Sn—Zn-based oxides, Sn—Ga—Zn-based oxides, Al—Ga—Zn-based oxides, Sn—Al—Zn-based oxides, In—Hf—Zn-based oxides, In—La—Zn-based oxides, In—Ce—Zn-based oxides, In—Pr—Zn-based oxides, In—Nd—Zn-based oxides, In—Sm—Zn-based oxides, In—Eu—Zn-based oxides, In—Gd—Zn-based oxides, In—Tb—Zn-based oxides, In—Dy-ternary metal oxides such as Zn-based oxides, In—Ho—Zn-based oxides, In—Er—Zn-based oxides, In—Tm—Zn-based oxides, In—Yb—Zn-based oxides, or In—Lu—Zn-based oxides; and In—Sn—Ga—Zn-based oxides, In—Hf—Ga—Zn-based oxides, In—Al—Ga—Zn-based oxides, In—Sn—Al—Zn-based oxides, In—Sn—Hf—Zn—based oxides and alternatively, it may include at least one of a quaternary metal oxide such as an In—Hf—Al—Zn-based oxide. For example, the first semiconductor layer 131, 132, and 133 may include Indium-Gallium-Zinc Oxide (IGZO) among the In—Ga—Zn-based oxides.

The first region 131 of the first semiconductor layer 131, 132, and 133 is a channel region, and the second region 132 and the third region 133 of the first semiconductor layer 131, 132, and 133 are a source region and a drain region.

The sheet resistance of the first region 131 that is the channel region of the first semiconductor layer 131, 132, and 133 is greater than the sheet resistances of the second region 132 and the third region 133 that are the source region and a drain region of the first semiconductor layer 131, 132, and 133, and the carrier concentration of the first region 131 is lower than the carrier concentrations of the second region 132 and the third region 133.

The second region 132 and the third region 133 of the first semiconductor layer 131, 132, and 133 may include an impurity, for example, an N-type impurity or a P-type impurity. For example, the N-type impurity may be P (phosphorus), As (arsenic), or Sb (antimony), and the P-type impurity may be B (boron), Al (13), or In (indium).

Impurities may not be included in the first region 131, which is a channel region of the first semiconductor layer 131, 132, and 133. Concentrations of the impurities in the second region 132 and the third region 133 of the first semiconductor layer 131, 132, and 133 may be higher than the concentration of the impurities in the first region 131 of the first semiconductor layer 131, 132, and 133.

The protection member 70 is disposed on the first region 131 of the first semiconductor layer 131, 132, and 133.

The protection member 70 may be disposed to overlap the first region 131 of the first semiconductor layer 131, 132, and 133. The protection member 70 is disposed on the first region 131 of the first semiconductor layer 131, 132, and 133, so that the first region 131 of the first semiconductor layer 131, 132, and 133 may be prevented from contacting the second semiconductor layers 162 and 163 and etching of the first region 131 of the first semiconductor layer 131, 132, and 133.

The second semiconductor layers 162 and 163 are disposed on the second region 132 and the third region 133 of the first semiconductor layer 131, 132, and 133. A portion of the second semiconductor layers 162 and 163 may be disposed on the protection member 70.

The second semiconductor layers 162 and 163 include a first portion 162 contacting the second region 132 of the first semiconductor layer 131, 132, and 133 and a second portion 163 contacting the third region 133 of the first semiconductor layer 131, 132, and 133. A portion of the first portion 162 and a portion of the second portion 163 of the second semiconductor layers 162 and 163 may be disposed on the protection member 70 to be spaced apart from each other.

The second semiconductor layers 162 and 163 include an amorphous silicon, and more specifically, the second semiconductor layers 162 and 163 include a hydrogenated amorphous silicon (a-Si:H).

The second semiconductor layers 162 and 163 may include impurities, for example, N-type impurities or P-type impurities.

The impurities included in the second semiconductor layers 162 and 163 and the impurities included in the second region 132 and the third region 133 of the first semiconductor layer 131, 132, and 133 may be the same.

The first portion 162 of the second semiconductor layers 162 and 163 is in ohmic contact with the second region 132 of the first semiconductor layer 131, 132, and 133, and the second portion 163 of the second semiconductor layers 162 and 163 is in ohmic contact with the third region 133 of the first semiconductor layer 131, 132, and 133.

The thickness of the second semiconductor layers 162 and 163 may be at least about 5 nm to about 60 nm, and the thickness of the second semiconductor layers 162 and 163 may be about 20 nm to about 60 nm. More specifically, when the thickness of the second semiconductor layers 162 and 163 is about 20 nm or more, the sheet resistances of the second region 132 and the third region 133 of the first semiconductor layer 131, 132, and 133 contacting the second semiconductor layers 162 and 163 may decrease, and the carrier concentrations of the second region 132 and the third region 133 may increase.

A source electrode 182 and a drain electrode 183 are disposed on the first portion 162 and the second portion 163 of the second semiconductor layers 162 and 163.

The source electrode 182 and the drain electrode 183 are patterned simultaneously with the first portion 162 and the second portion 163 of the second semiconductor layers 162 and 163, so that the source electrode 182 and the second portion 162 may have the same planar shape and the drain electrode 183 and the second portion 163 may have the same planar shape.

The source electrode 182 and the drain electrode 183 may include an aluminum-based metal, a silver-based metal, or a copper-based metal having low resistivity, and for example, may be three-layered of a lower film containing a refractory metal such as titanium, molybdenum, chromium, tantalum, or an alloy thereof, an intermediate film containing a low resistivity aluminum-based metal, a silver-based metal, or a copper-based metal, and an upper film containing a refractory metal such as titanium, molybdenum, chromium, and tantalum.

A passivation layer 170 is disposed on the second semiconductor layers 162 and 163, the protection member 70, and the gate insulating layer 141. The passivation layer 170 may include at least one of a silicon nitride, a silicon oxide, a silicon oxynitride, and tetraethyl orthosilicate (TEOS), and it may be made of an organic material such a polyacrylate resin or a polyimide resin or may be a laminated film of the organic material and the inorganic material.

The gate electrode 151, the source electrode 182, and the drain electrode 183 form a thin film transistor (TFT) together with the first semiconductor layer 131, 132, and 133 and the second semiconductor layers 162 and 163. The channel of the thin film transistor is formed in the first region 131 between the second region 132 serving as the source region and the third region 133 serving as the drain region of the semiconductors 131, 132, and 133.

Next, a method of manufacturing a thin film transistor according to another embodiment will be described with reference to FIG. 9.

A gate electrode 151 is formed on the substrate 110, and a gate insulating layer 141 is deposited on the substrate 110 including the gate electrode 151.

An oxide semiconductor layer is deposited on the gate insulating layer 141, and a protection member 70 is formed to overlap the first region 131 that is the channel region of the transistor among the oxide semiconductor layers.

Hydrogenated amorphous silicon (a-Si:H) is deposited on the oxide semiconductor layer and the protective member 70.

By depositing the hydrogenated amorphous silicon layer on the oxide semiconductor layer and the protective member 70, the second region 132 and the third region 133 not overlapping the protective member 70 among the oxide semiconductor layer are metallized by hydrogen included in the second semiconductor layer 160 to form a source region and a drain region, and at the same time, the first region 131 that is a channel region overlapping the protective member 70 is formed between the second region 132 and the third region 133.

A metal layer forming the source electrode 182 and the drain electrode 183 is deposited on the hydrogenated amorphous silicon layer.

Next, the metal layer forming the source electrode 182 and the drain electrode 183 and the hydrogenated amorphous silicon layer forming the second semiconductor layer are patterned together to form the second semiconductor layers 162 and 163 including the first portion 162 contacting the second region 132 of the first semiconductor layer 131, 132, and 133 and the second portion 163 contacting the third region 133 of the first semiconductor layer 131, 132, and 133, and the source electrode 182 and the drain electrode 183 together. In this case, the protection member 70 may serve as an etch stop layer that prevents the first region 131 of the first semiconductor layer 131, 132, and 133 from being etched.

By depositing the second semiconductor layers 162 and 163 on the source region 132 and the drain region 133 of the first semiconductor layer 131, 132, and 133, the sheet resistance of the first region 131 that is the channel of the first semiconductor layer 131, 132, and 133 is greater than the sheet resistances of the second region 132 and the third region 133 that are the source region and the drain region of the first semiconductor layer 131, 132, and 133, and the carrier concentration of the first region 131 is lower than the carrier concentrations of the second region 132 and the third region 133.

The second semiconductor layer 160 may include impurities, for example, N-type impurities or P-type impurities. The impurities contained in the second semiconductor layer 160 are diffused into the second region 132 and the third region 133 of the first semiconductor layer 131, 132, and 133 contacting the second semiconductor layer 160, and therefore the impurities included in the second semiconductor layer 160 may be the same as impurities included in the second region 132 and the third region 133 of the first semiconductor layer 131, 132, and 133.

The first portion 162 of the second semiconductor layers 162 and 163 is in ohmic contact with the second region 132 of the first semiconductor layer 131, 132, and 133, and the second portion 163 of the second semiconductor layers 162 and 163 is in ohmic contact with the third region 133 of the first semiconductor layer 131, 132, and 133.

The thickness of the second semiconductor layers 162 and 163 may be at least about 5 nm to about 60 nm, and the thickness of the second semiconductor layers 162 and 163 may be about 20 nm to about 60 nm. More specifically, when the thickness of the second semiconductor layers 162 and 163 is about 20 nm or more, the sheet resistances of the second region 132 and the third region 133 of the first semiconductor layer 131, 132, and 133 contacting the second semiconductor layers 162 and 163 may decrease, and the carrier concentrations of the second region 132 and the third region 133 may increase.

Next, a passivation layer 170 is deposited on the second semiconductor layers 162 and 163, the protection member 70, and the gate insulating layer 141.

As such, according to the thin film transistor according to the embodiment, by depositing the second semiconductor layer including a hydrogenated amorphous silicon (a-Si:H) on the first semiconductor layer including an oxide semiconductor, the second region 132 and the third region 133 contacting the second semiconductor layer are metallized by hydrogen included in the second semiconductor layer to form a source region and a drain region, and at the same time, the first region 131 that is a channel region may be formed between the second region 132 and the third region 133 of the first semiconductor layer.

In addition, the metal layer forming the source electrode 182 and the drain electrode 183 and the hydrogenated amorphous silicon layer forming the second semiconductor layer are patterned together to form the second region 132 of the first semiconductor layer 131, 132, and 133. The second semiconductor layers 162 and 163 include the first portion 162 and the second portion 163 contacting the third region 133 of the first semiconductor layer 131, 132, and 133; and in addition, the source electrode 182 and the drain electrode 183 may be formed together. Accordingly, the performance of the transistor can be improved by forming the channel region, the source region, and the drain region in the semiconductor layer including the oxide semiconductor, without complicating the manufacturing process or increasing the manufacturing cost, and contact characteristics between the source region and the source electrode and between the drain region and the drain electrode may be improved.

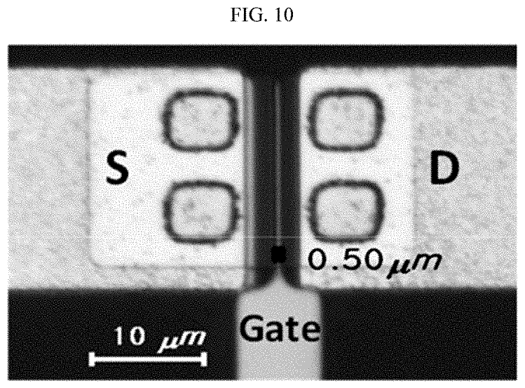

Now, an experimental example will be described with reference to FIG. 10 to FIG. 12. FIG. 10 to FIG. 12 are photographs showing the results of one experimental example.

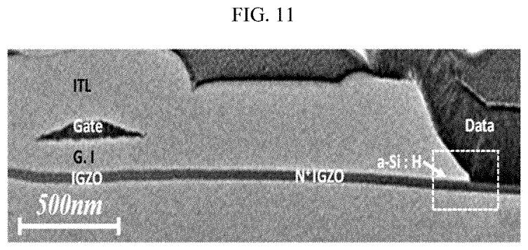

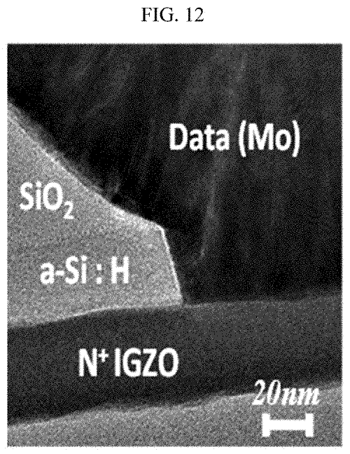

In this experimental example, a thin film transistor was formed according to the method for manufacturing a thin film transistor described above with reference to FIGS. 2 to 8 together with FIG. 1, and the results are shown in FIG. 10 to FIG. 12 as electron micrographs. FIG. 10 is a plan photograph of the formed thin film transistor, FIG. 11 is a cross-sectional photograph of a portion of the formed thin film transistor, and FIG. 12 is an enlarged photograph illustrating the rectangular portion of FIG. 11.

Referring to FIG. 10, it can be seen that the thin film transistor including the gate electrode GATE, the source electrode S, and the drain electrode D was well formed.

Referring to FIG. 11 and FIG. 12, It can be seen that each pattern of a channel region (IGZO) of the first semiconductor layer, a drain region (N+IGZO) of the first semiconductor layer, a second portion (a-Si:H) of the second semiconductor layer, a gate insulating layer (GI), the gate electrode (Gate), the passivation layer (ITL, SiO2), and the drain electrode (Data (Mo)) were well formed.

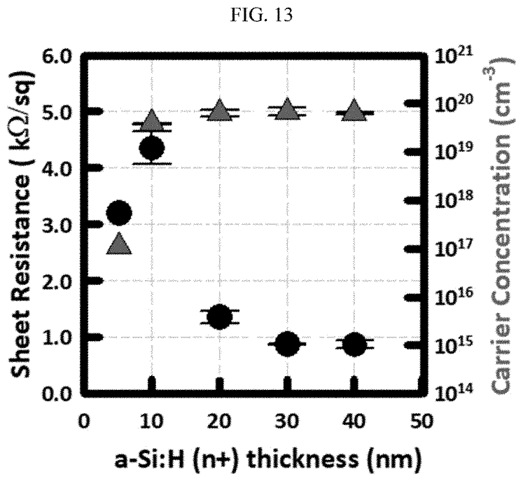

Next, another experimental example will be described with reference to Table 1 to Table 3 together with FIG. 13 to FIG. 15. FIG. 13 to FIG. 15 are graphs showing the results of another experimental example, and Table 1 to Table 3 are tables showing the results of another experimental example.

In this experimental example, as with the thin film transistors according to the embodiments, thin film transistors including the first semiconductor layers including an oxide semiconductor and the second semiconductor layers contacting the source regions and the drain regions of the first semiconductor layers and including a hydrogenated amorphous silicon were formed, while each of the first semiconductor layer 130 of the thin film transistors was formed to include different oxide semiconductors and the layer thickness of the second semiconductor layer 160 was changed, sheet resistances and carrier concentrations of the channel region were measured, and the results were shown in a graph.

In this experimental example, in the first case in which the first semiconductor layer 130 was formed to include amorphous indium-gallium-zinc-oxide (a-IGZO), in the second case in which the first semiconductor layer 130 was formed to include zinc oxide (ZnOx), and in the third case in which the first semiconductor layer 130 was formed to include indium oxide (InOx), the second semiconductor layer 160 including the hydrogenated amorphous silicon (a-Si:H) containing N-type impurities were formed to have thicknesses of about 10 nm, about 20 nm, about 30 nm, about 40 nm, and about 50 nm, and then the sheet resistances and carrier concentrations of the thin film transistors were measured.

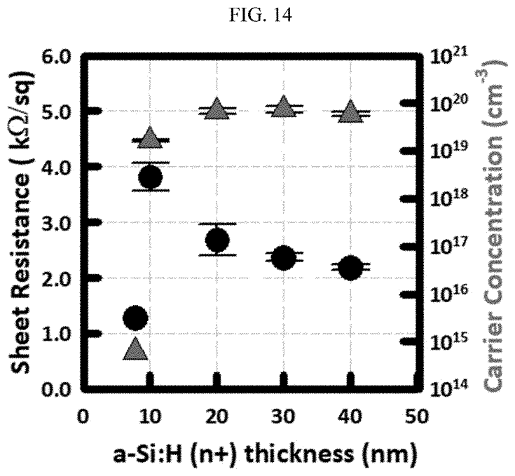

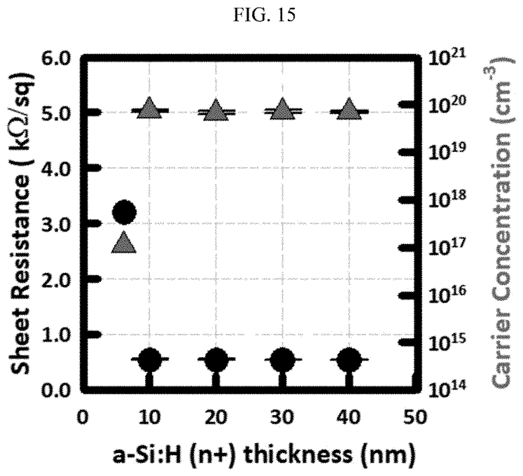

FIG. 13 and Table 1 show the results of the first case in which the first semiconductor layer 130 was formed to include amorphous indium-gallium-zinc-oxide (a-IGZO), and FIG. 14 and Table 2 show the results of the second case in which the first semiconductor layer 130 was formed to include zinc oxide (ZnOx), and FIG. 15 and Table 3 show the results of the third case in which the first semiconductor layer 130 was formed to include indium oxide (InOx).

Referring to Table 1 to Table 3 together with FIG. 13 to FIG. 15, as with the thin film transistor according to the embodiment, according to the thin film transistors that include the first semiconductor layer including the oxide semiconductor and the second semiconductor layer including the hydrogenated amorphous silicon (a-Si:H) and contacting the source region and the drain region of the first semiconductor layer, it was found that the sheet resistances were decreased and the carrier concentrations were increased when the second semiconductor layer 160 was formed on the first semiconductor layer 130 regardless of the type of oxide semiconductor included in the first semiconductor layer 130. In particular, it was found that when the thickness of the second semiconductor layer 160 was formed to be about 20 nm or more, more specifically, about 30 nm or more, the value of the carrier concentration was increased while the value of the sheet resistance was decreased.

TABLE 1

| | | | | |
|---|---|---|---|---|
| Thickness of | 10 | 20 | 30 | 40 |
| the second | | | | |
| semiconductor | | | | |
| layer (nm) | | | | |
| Sheet resistance | 3.2 | 1.5 | 0.8 | 0.8 |
| (kΩ/□) | | | | |
| Carrier | 3.8 × 10¹⁹ | 5.8 × 10¹⁹ | 6.2 × 10¹⁹ | 6.5 × 10¹⁹ |
| concentration cm⁻³ | | | | |

TABLE 2

| | | | | |
|---|---|---|---|---|
| Thickness of | 10 | 20 | 30 | 40 |
| the second | | | | |
| semiconductor | | | | |
| layer (nm) | | | | |
| Sheet resistance | 4.1 | 2.6 | 2.2 | 2.1 |
| (kΩ/□) | | | | |
| Carrier | 1.6 × 10¹⁹ | 6.5 × 10¹⁹ | 7.1 × 10¹⁹ | 6.9 × 10¹⁹ |
| concentration cm⁻³ | | | | |

TABLE 3

| | | | | |
|---|---|---|---|---|
| Thickness of | 10 | 20 | 30 | 40 |
| the second | | | | |
| semiconductor | | | | |
| layer (nm) | | | | |
| Sheet resistance | 0.5 | 0.5 | 0.5 | 0.5 |
| (kΩ/□) | | | | |
| Carrier | 7.1 × 10¹⁹ | 7.2 × 10¹⁹ | 7.4 × 10¹⁹ | 7.4 × 10¹⁹ |
| concentration cm⁻³ | | | | |

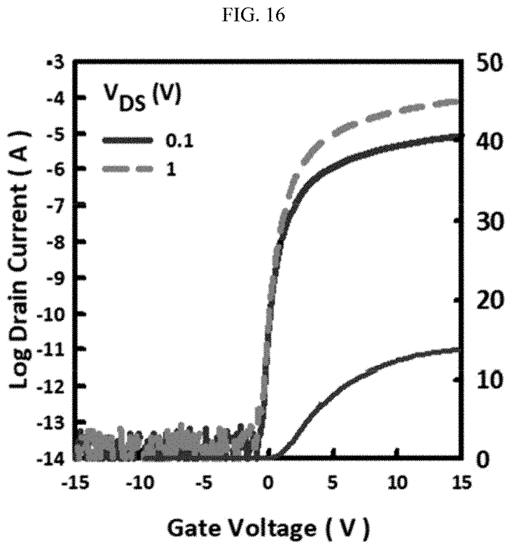

Another experimental example will be described with reference to FIG. 16 to FIG. 18. FIG. 16 to FIG. 18 are graphs showing results of another experimental example. In this experimental example, as with the thin film transistor according to the embodiment, the thin film transistor including the first semiconductor layer including amorphous indium-gallium-zinc-oxide (a-IGZO) and the second semiconductor layer including hydrogenated amorphous silicon (a-Si:H) containing N-type impurities was formed and the characteristics of the thin film transistor were measured.

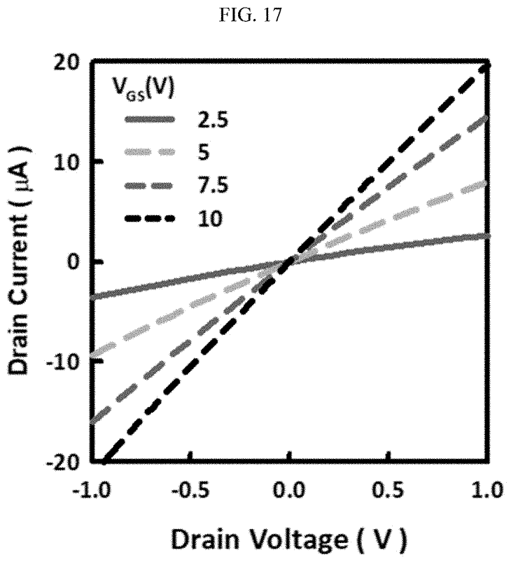

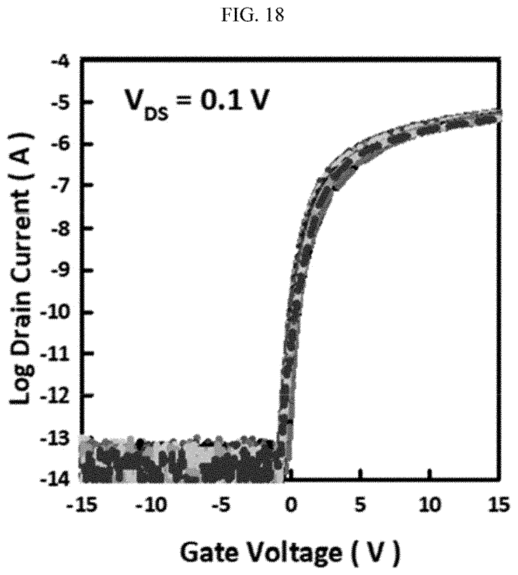

A transfer curve and field effect mobility of the thin film transistor are shown in FIG. 16, an output curve of the thin film transistor is shown in FIG. 17, and transfer curves measured at 25 different positions in the first semiconductor layer 130 having the horizontal width and the vertical width of about 15 cm are shown in FIG. 18.

Referring to FIG. 16, as with the thin film transistor according to the embodiment, according to the thin film transistor that includes the first semiconductor layer including the oxide semiconductor and the second semiconductor layer including the hydrogenated amorphous silicon (a-Si:H) and contacting the source region and the drain region of the first semiconductor layer, it was found that the on-off characteristic of the transistor was well represented when the source-drain voltage V_{DS} was 0.1 V and 1 V. In addition, it was found that the field effect mobility increased well as the gate voltage increased.

Referring to FIG. 17, as with the thin film transistor according to the embodiment, according to the thin film transistor that includes the first semiconductor layer including the oxide semiconductor and the second semiconductor layer including the hydrogenated amorphous silicon (a-Si:H) and contacting the source region and the drain region of the first semiconductor layer, it was found that the drain current with respect to the drain voltage was linearly changed within the range of −1 V to 1 V of the drain voltage when the gate voltage V_{GS} is 2.5 V, 5 V, 7.5 V, or 10 V. Through this, it was confirmed that ohmic contacts were made between the source region and the source electrode and between the drain region and the drain electrode.

Referring to FIG. 18, as with the thin film transistor according to the embodiment, according to the thin film transistor that includes the first semiconductor layer including the oxide semiconductor and the second semiconductor layer including the hydrogenated amorphous silicon (a-Si:H) and contacting the source region and the drain region of the first semiconductor layer, it was found that that the on-off characteristic of the transistor was uniformly well represented at 25 different positions of the first semiconductor layer 130 of the thin film transistor.

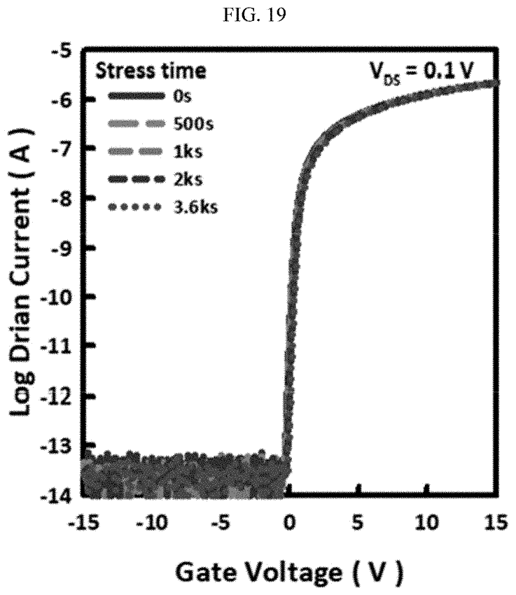

Now, another experimental example will be described with reference to Table 4 to Table 6 together with FIG. 19 to FIG. 21. FIG. 19 to FIG. 21 are graphs showing results of another experimental example.

In this experimental example, as with the thin film transistor according to the embodiment, the thin film transistor including the first semiconductor layer including amorphous indium-gallium-zinc-oxide (a-IGZO) and the second semiconductor layer including hydrogenated amorphous silicon (a-Si:H) containing N-type impurities was formed and the characteristic of the thin film transistor according to the stress time and Subthreshold Swing (SS) that is the amount of change in voltage according to the change in current when the threshold voltage (V_{TH}) and a voltage below the threshold voltage is applied were measured. At this time, the gate voltage (Vgs) was applied to −20 V and 20 V, and was measured under the condition of about 60 degrees.

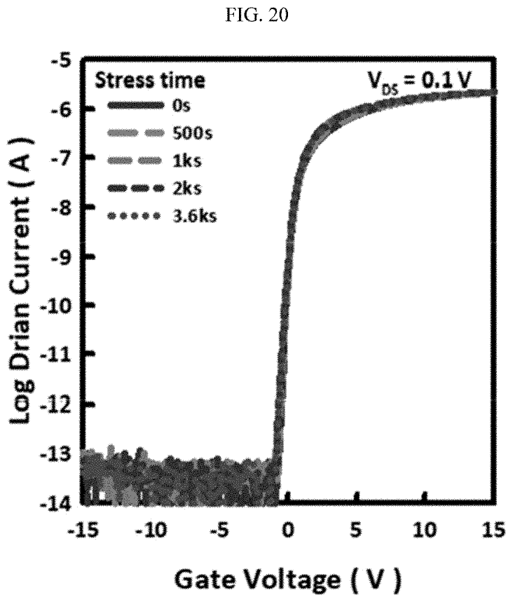

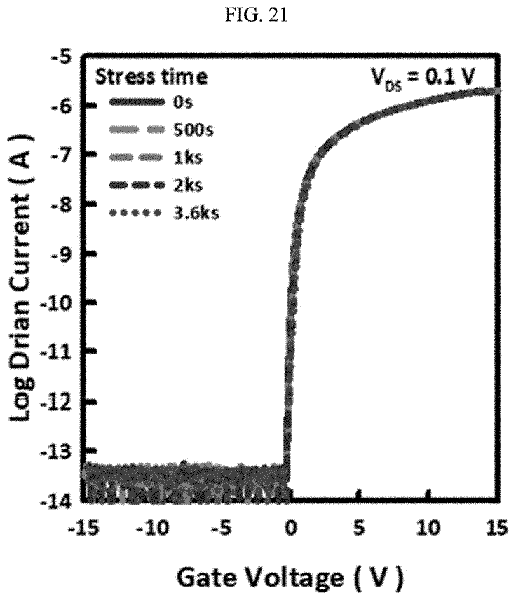

FIG. 19 and Table 4 show the results of negative bias temperature stress (NBTS), FIG. 20 and Table 5 show the results of positive bias temperature stress (PBTS), and FIG. 21 and Table. 6 show the results of high current temperature stress (HCTS).

TABLE 4

| | | | | | |
|---|---|---|---|---|---|
| Stress time (s) | 0 | 500 | 1000 | 2000 | 3600 |
| V_{TH}(V) | 0.1 | 0.1 | 0.1 | 0.1 | 0.1 |
| SS (V/dec) | 0.12 | 0.12 | 0.12 | 0.12 | 0.12 |

TABLE 5

| | | | | | |
|---|---|---|---|---|---|
| Stress time (s) | 0 | 500 | 1000 | 2000 | 3600 |
| V_{TH} (V) | −0.1 | −0.1 | −0.1 | −0.1 | −0.1 |
| SS (V/dec) | 0.16 | 0.16 | 0.16 | 0.16 | 0.16 |

TABLE 6

| | | | | | |
|---|---|---|---|---|---|
| Stress time (s) | 0 | 500 | 1000 | 2000 | 3600 |
| V_{TH} (V) | 0.0 | 0.0 | 0.0 | 0.0 | 0.0 |
| SS (V/dec) | 0.13 | 0.13 | 0.13 | 0.13 | 0.13 |

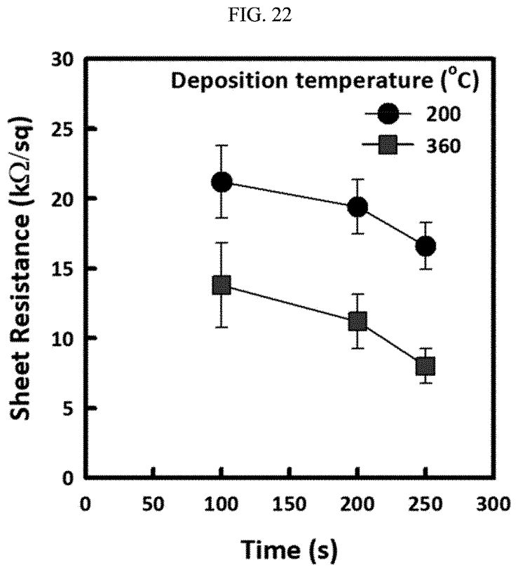

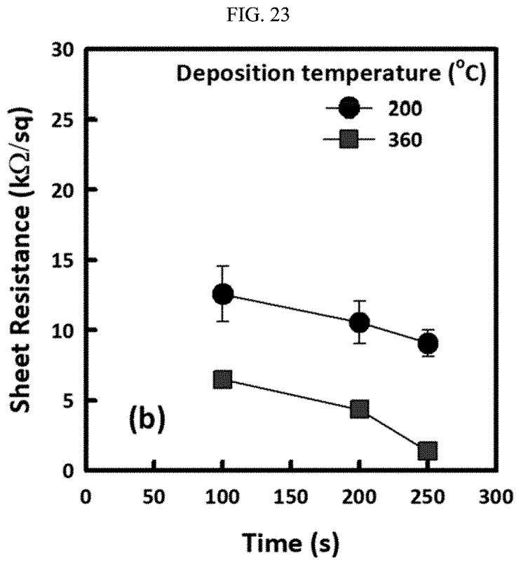

Referring to Tables 4 to 6 together with FIG. 19 to FIG. 21, as with the thin film transistor according to the embodiment, according to the thin film transistor that includes the first semiconductor layer including the oxide semiconductor and the second semiconductor layer including the hydrogenated amorphous silicon (a-Si:H) and contacting the source region and the drain region of the first semiconductor layer, it was found that that the threshold voltage (VTH) and the subthreshold swing (SS) do not change even when the stress time increases. With reference to FIG. 22 and FIG. 23, another experimental example will be described. FIG. 22 and FIG. 23 are graphs showing results of another experimental example.

In this experimental example, in a case in which a thin film transistor including only a first semiconductor including an oxide semiconductor was formed, and in a case in which the thin film transistor that includes the first semiconductor layer including the oxide semiconductor and the second semiconductor layer including the hydrogenated amorphous silicon (a-Si:H) and contacting the source region and the drain region of the first semiconductor layer as with the thin film transistor according to the embodiment was formed, the sheet resistance values of the thin film transistors according to the depositing time were measured in an atmosphere where the temperature of the chamber was 200 degrees and 360 degrees and the results are shown in FIG. 22 and FIG. 23.

FIG. 22 shows a result in the case of forming the thin film transistor including only the first semiconductor including an oxide semiconductor, and FIG. 23 shows a result in the case of forming the thin film transistor that includes the first semiconductor layer including the oxide semiconductor and the second semiconductor layer including the hydrogenated amorphous silicon (a-Si:H) and contacting the source region and the drain region of the first semiconductor layer as with the thin film transistor according to the embodiment.

Referring to FIG. 22 and FIG. 23, compared to the thin film transistor including only the first semiconductor including an oxide semiconductor, in the thin film transistor that includes the first semiconductor layer including the oxide semiconductor and the second semiconductor layer including the hydrogenated amorphous silicon (a-Si:H) and contacting the source region and the drain region of the first semiconductor layer as with the thin film transistor according to the embodiment, it was found that the sheet resistance of the thin film transistor was smaller, and the sheet resistance of the transistor became smaller as the depositing time of the second semiconductor layer increased.

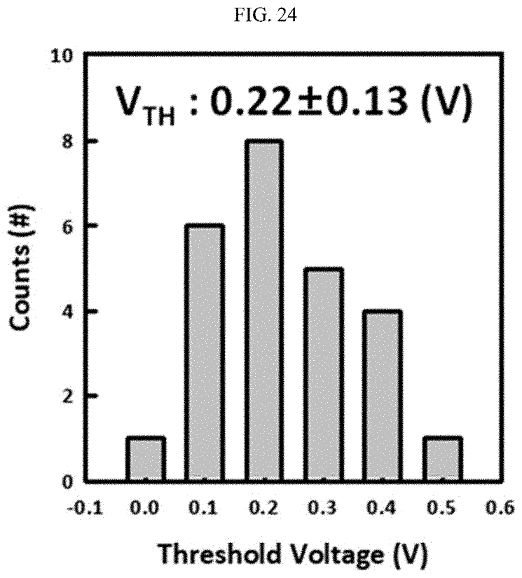

Another experimental example will be described with reference to FIG. 24 to FIG. 26. FIG. 24 to FIG. 26 are graphs showing results of another experimental example.

In this experimental example, as with the thin film transistor according to the embodiment, the thin film transistor including the first semiconductor layer including amorphous indium-gallium-zinc-oxide (a-IGZO) and the second semiconductor layer including hydrogenated amorphous silicon (a-Si:H) containing N-type impurities was formed and the characteristics of the thin film transistor were measured. The width and length of the first semiconductor layer 130 was formed to be about 15 cm, and the characteristics measured at 25 different positions are shown in FIG. 24 to FIG. 26.

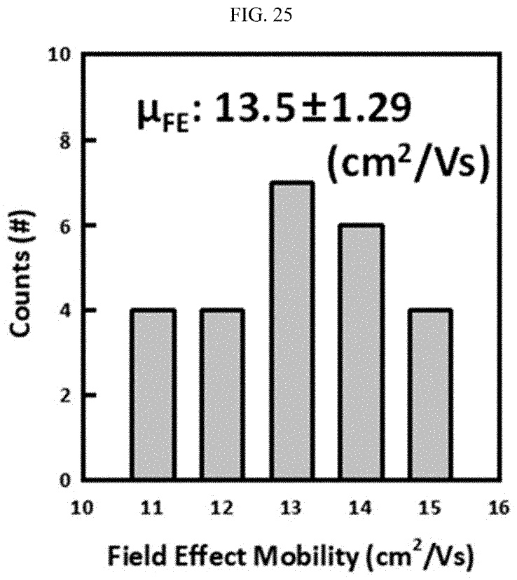

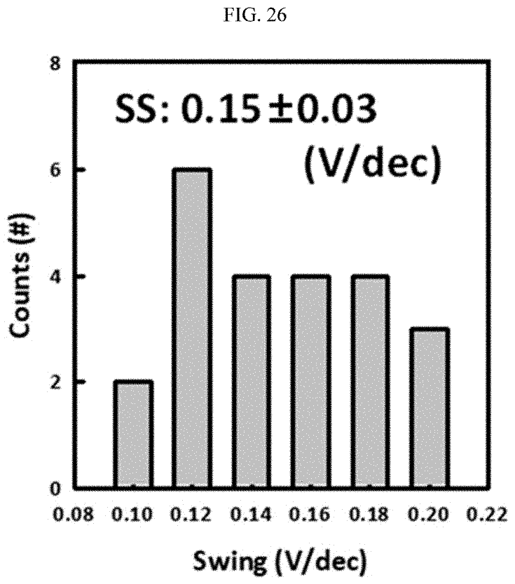

FIG. 24 shows the distribution of threshold voltage values, FIG. 25 shows the distribution of field effect mobility values, and FIG. 26 shows the distribution of the swing values below the threshold voltage.

As with the thin film transistor according to the embodiment, in the thin film transistor including the first semiconductor layer including amorphous indium-gallium-zinc-oxide (a-IGZO) and the second semiconductor layer including hydrogenated amorphous silicon (a-Si:H) containing N-type impurities was formed, it was found that the threshold voltage value had a distribution of 0.22±0.13 V the field effect mobility had a distribution of 13.5±1.29 (cm2/Vs), and the swing value below the threshold voltage had a distribution of 0.15±0.03 (V/dec), referring to FIG. 24 to FIG. 26.

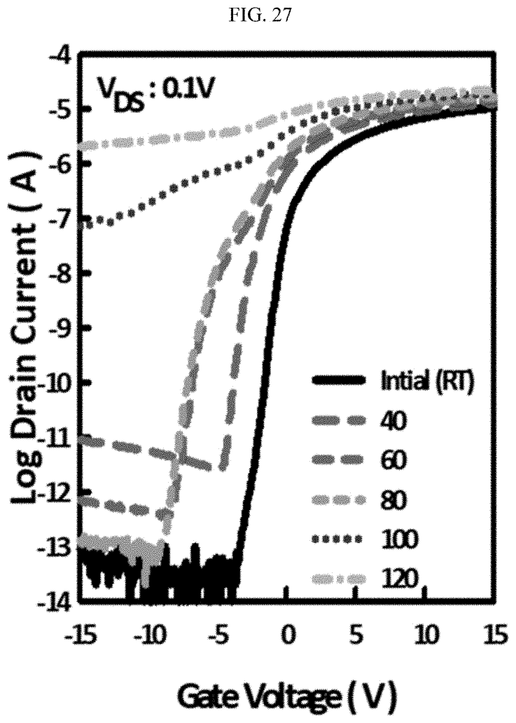

Another experimental example will be described with reference to FIG. 27 and FIG. 28 and FIG. 29 and FIG. 30. FIG. 27 and FIG. 28 and FIG. 29 and FIG. 30 are graphs showing results of another experimental example.

In this experimental example, in the first case in which a thin film transistor including only a first semiconductor including indium-gallium-zinc-oxide was formed and a source region and a drain region of the oxide semiconductor were doped with fluorine, and in the second case in which a thin film transistor including the first semiconductor layer containing indium-gallium-zinc-oxide and the second semiconductor layer including a hydrogenated amorphous silicon and contacting the source region and the drain region of the first semiconductor layer was formed, transfer curves were measured while changing the temperature to 40 degrees, 60 degrees, 80 degrees, 100 degrees, and 120 degrees and when the channel length was about 1 μm and the channel length was about 6 μm.

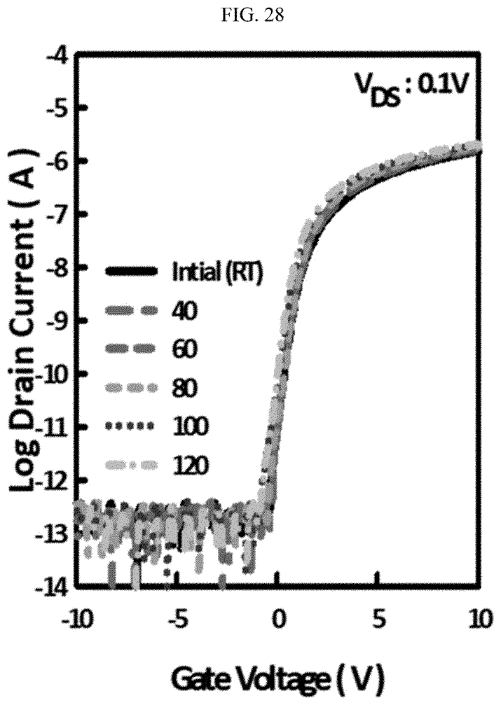

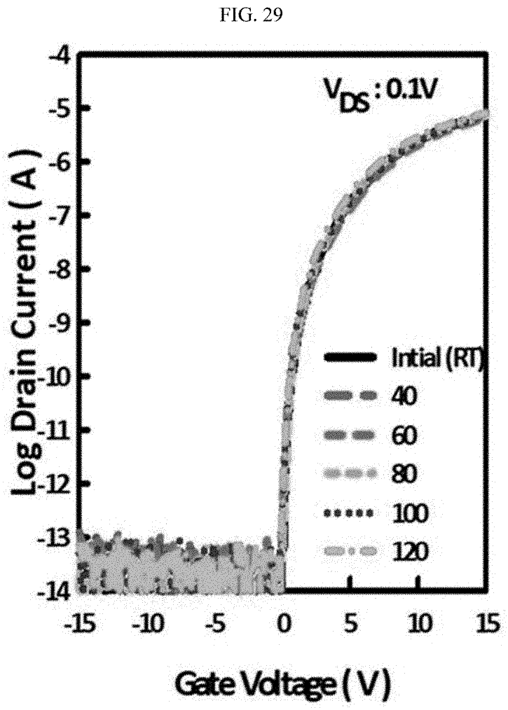

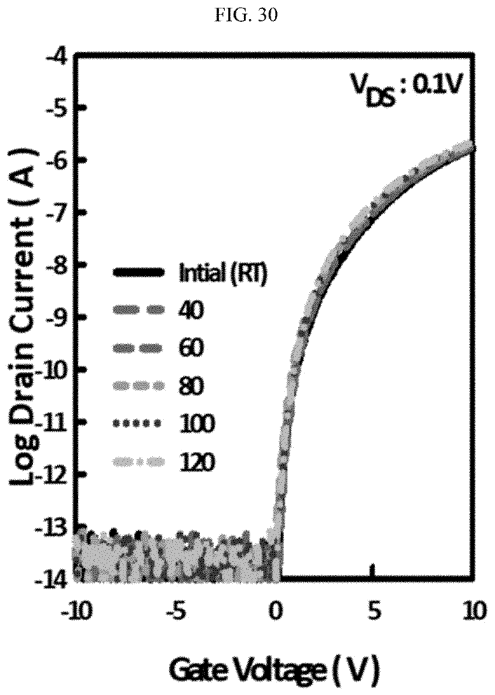

FIG. 27 and FIG. 28 show the result of the first case, and FIG. 29 and FIG. 30 show the result in the second case. FIG. 27 and FIG. 29 show the result when the channel length was 1 μm, FIG. 28 and FIG. 30 show the result when the channel length was 6 μm.

Referring to FIG. 29 and FIG. 30 along with FIG. 27 and FIG. 28, compared to the first case in which the thin film transistor including only the first semiconductor including indium-gallium-zinc-oxide and the source region and the drain region of the oxide semiconductor were doped with fluorine as with a conventional thin film transistor including an oxide semiconductor, in the second case in which the thin film transistor including the first semiconductor layer containing indium-gallium-zinc-oxide and the second semiconductor layer including a hydrogenated amorphous silicon and contacting the source region and the drain region of the first semiconductor layer was formed as with the thin film transistor according to the embodiment, it was found that the on-off characteristic of the thin film transistor did not change according to the temperature change regardless of the channel length and the characteristic of the thin film transistor according to the temperature was more stable, and the characteristic of the thin film transistor was better.

While this disclosure has been described in connection with what is presently considered to be practical embodiments, it is to be understood that the invention is not limited to the disclosed embodiments, but, on the contrary, is intended to cover various modifications and equivalent arrangements included within the spirit and scope of the appended claims.

<Description of symbols>

| | |
|---|---|
| 110: substrate | 120: buffer layer |
| 130: first semiconductor layer | 131: first region |
| 132: second region | 133: third region |
| 141: gate insulating layer | 151: gate electrode |
| 160: second semiconductor layer | 162: first portion |
| 163: second portion | 170: passivation layer |
| 172, 173: contact hole | 182: source electrode |
| 183: drain electrode | |

What is claimed is:

1. A thin film transistor comprising:
a first semiconductor;
a gate electrode overlapping the first semiconductor;
a second semiconductor contacting a portion of the first semiconductor; and
a source electrode and a drain electrode contacting the second semiconductor,
wherein the first semiconductor comprises an oxide semiconductor, and the second semiconductor comprises silicon.

2. The thin film transistor of claim 1, wherein:
the first semiconductor comprises a channel region overlapping the gate electrode; and
a source region and a drain region contacting the second semiconductor,
wherein the second semiconductor comprises a first portion contacting the source region of the first semiconductor and a second portion contacting the drain region of the first semiconductor.

3. The thin film transistor of claim 2, wherein
resistances of the source region and the drain region of the first semiconductor are reduced by the second semiconductor contacting the first semiconductor.

4. The thin film transistor of claim 2, wherein
the source region of the first semiconductor and the first portion of the second semiconductor are in ohmic contact with the source electrode, and
the drain region of the first semiconductor and the second portion of the second semiconductor are in ohmic contact with the drain electrode.

5. The thin film transistor of claim 1, wherein
the second semiconductor includes a hydrogenated amorphous silicon.

6. The thin film transistor of claim 4, wherein
the second semiconductor includes a first impurity of an N-type or a second impurity of a P-type, and
the first semiconductor includes the first impurity or the second impurity of the second semiconductor.

7. The thin film transistor of claim 3, wherein
values of sheet resistances of the source region and the drain region of the first semiconductor are lower than a value of a sheet resistance of the channel region, and
values of carrier concentrations of the source region and the drain region of the first semiconductor are greater than a value of a carrier concentration of the channel region.

8. The thin film transistor of claim 3, wherein
a thickness of the second semiconductor is at least 5 nm to 60 nm.

9. The thin film transistor of claim 1, wherein
the first semiconductor includes a source region, a drain region, and a channel region between the source region and the drain region,
the second semiconductor includes a first portion contacting the source region and a second portion contacting the drain electrode,
further comprising a protection member disposed on the channel region of the first semiconductor layer, and
the first portion and the second portion of the second semiconductor layer overlap a portion of the protection member and are spaced apart from each other on the protection member.

10. The thin film transistor of claim 9, wherein
the source electrode is disposed on the first portion of the second semiconductor, and the drain electrode is disposed on the second portion of the second semiconductor, and
the first portion of the second semiconductor and the source electrode are patterned together to have the same planar shape, and the second portion of the second semiconductor and the drain electrode are patterned together to have the same planar shape.

11. The thin film transistor of claim 10, wherein
the second semiconductor includes a hydrogenated amorphous silicon.

12. The thin film transistor of claim 10, wherein
the second semiconductor includes a first impurity of an N-type or a second impurity of a P-type, and
the first semiconductor includes the first impurity or the second impurity of the second semiconductor.

13. The thin film transistor of claim 10, wherein
a thickness of the second semiconductor is at least 5 nm to 60 nm.

14. A manufacturing method of a thin film transistor, comprising:
forming a first semiconductor layer including an oxide semiconductor;
forming a gate electrode overlapping the first semiconductor layer;
depositing a second semiconductor layer including silicon on the first semiconductor layer and the gate electrode to contact a portion of the first semiconductor layer; and
forming a source electrode and a drain electrode contacting the second semiconductor layer.

15. The manufacturing method of claim 14, wherein
the first semiconductor layer is formed to include a channel region overlapping the gate electrode, and a source region and a drain region contacting the second semiconductor layer, and
the second semiconductor layer is formed to include a first portion contacting the source region of the first semiconductor and a second portion contacting the drain region of the first semiconductor.

16. The manufacturing method of claim 15, wherein
the second semiconductor includes a hydrogenated amorphous silicon.

17. The manufacturing method of claim 16, further comprising
patterning the second semiconductor layer to form the first portion contacting the source region of the first semiconductor and the second portion contacting the drain region of the first semiconductor.

18. The manufacturing method of claim 17, further comprising
forming a protection member on the channel region of the first semiconductor,
wherein the source electrode is formed to be disposed on the first region of the second semiconductor and the drain electrode is formed to be disposed on the second portion of the second semiconductor, and
the first portion of the second semiconductor and the source electrode are patterned together and the second portion of the second semiconductor and the drain electrode are patterned together.

19. The manufacturing method of claim 16, wherein
the second semiconductor is formed to include a first impurity of an N-type or a second impurity of a P-type, and
the first semiconductor is formed to include the first impurity or the second impurity of the second semiconductor.

20. The manufacturing method of claim 16, wherein
the second semiconductor is formed to have a thickness of at least 5 nm to 60 nm.
